(19) United States
(12) Patent Application Publication
(10) Pub. No.: US 2021/0020577 A1
(43) Pub. Date: Jan. 21, 2021

(54) SEMICONDUCTOR PACKAGE AND MANUFACTURING METHOD THEREOF

(71) Applicant: Dyi-Chung HU, Hsinchu (TW)

(72) Inventor: Dyi-Chung HU, Hsinchu (TW)

(21) Appl. No.: 16/835,235

(22) Filed: Mar. 30, 2020

Related U.S. Application Data
(60) Provisional application No. 62/874,970, filed on Jul. 16, 2019.

(51) Int. Cl. H01L 23/538; H01L 25/065; H01L 23/31; H01L 23/66; H01L 21/683; H01L 21/48; H01L 21/56; H01L 25/00; H01Q 1/22

(52) U.S. Cl. CPC H01L 23/5389; H01L 2225/06586; H01L 23/3128; H01L 23/5383; H01L 23/5386; H01L 23/66; H01L 21/6835; H01L 21/4853; H01L 21/4857; H01L 21/565; H01L 21/568; H01L 25/50; H01Q 1/2283; H01L 2221/68372; H01L 2223/6677; H01L 2225/06517; H01L 2225/06558; H01L 2225/06572; H01L 25/0652

(57) ABSTRACT

A semiconductor package including a first redistribution layer, a first die, a conductive connector, and a first insulating encapsulation is provided. The first die is disposed on and electrically connected to the first redistribution layer. The conductive connector is disposed on and electrically connected to the first redistribution layer. The conductive connector is disposed aside the first die. The first insulating encapsulation is disposed on the first redistribution layer and encapsulates the first die and the conductive connector. A manufacturing method of a semiconductor package is also provided.

### CROSS-REFERENCE TO RELATED APPLICATION

This application claims the priority benefit of U.S. provisional application Ser. No. 62/874,970, filed on Jul. 16, 2019. The entirety of the above-mentioned patent application is hereby incorporated by reference herein and made a part of this specification.

### BACKGROUND

### Technical Field

This disclosure relates to a package structure and a manufacturing method thereof.

### Description of Related Art

With the advancement of technology, the functions of electronic products are becoming more and more abundant. For example, in the current mobile communication device, in order to configure electronic components with different functions in one mobile communication device, the size of each electronic component is small for being possible to arrange all electronic components in the mobile communication device with the concept of light and thin.

### SUMMARY

The disclosure provides a single semiconductor package having multiple dies or active/passive component(s) integrated therein.

A semiconductor package of the present disclosure comprises a first redistribution layer, a first die, a conductive connector, and a first insulating encapsulation. The first die is disposed on and electrically connected to the first redistribution layer. The conductive connector is disposed on and electrically connected to the first redistribution layer. The conductive connector is disposed aside the first die. The first insulating encapsulation is disposed on the first redistribution layer and encapsulates the first die and the conductive connector.

In an embodiment, the semiconductor package further comprises a conductive terminal. The conductive terminal is disposed on and electrically connected to the conductive connector. Each of the conductive connectors has a protruded portion protruded from the first insulating encapsulation. The conductive terminals cover the protruded portions of the conductive connectors.

In an embodiment, the semiconductor package further comprises a third die.

The third die is disposed on and electrically connected to the first redistribution layer. The third die and the first die are disposed on two opposite sides of the first redistribution layer. The first die is electrically coupled to the third die through the first redistribution layer.

In an embodiment, the semiconductor package further comprises a second die. The second die is disposed on and electrically connected to the first redistribution layer. The second die is disposed aside the first die and is encapsulated by the first insulating encapsulation.

In an embodiment, the semiconductor package further comprises a third die, a second die, and a conductive terminal. The third die is disposed on and electrically connected to the first redistribution layer. The third die and the first die are disposed on two opposite sides of the first redistribution layer. The first die is electrically coupled to the third die through the first redistribution layer. The second die is disposed on and electrically connected to the first redistribution layer. The second die is disposed aside the first die and is encapsulated by the first insulating encapsulation. The conductive terminal is disposed on and electrically connected to the conductive connector. At least one of the first die, the second die, or the third die is electrically coupled to the conductive terminal through the first redistribution layer and the conductive connector.

In an embodiment, the semiconductor package further comprises a conductive terminal and a second redistribution layer. The conductive terminal is disposed on and electrically connected to the conductive connector. The second redistribution layer is disposed on the first insulating encapsulation and electrically connected to the conductive connectors. The plurality of conductive terminals are formed on the second redistribution layer and electrically connected to the second redistribution layer.

In an embodiment, the top surfaces of conductive connectors and the top surface of the first insulating encapsulation are coplanar.

In an embodiment, the semiconductor package further comprises a third die, a second insulating encapsulation, a conductive through via, and an antenna pattern. The third die is disposed on and electrically connected to the first redistribution layer. The third die and the first die are disposed on two opposite sides of the first redistribution layer. The first die is electrically coupled to the third die through the first redistribution layer. The second insulating encapsulation is disposed on the first redistribution layer and encapsulates the third die. The conductive through via penetrates through the second insulating encapsulation to be connected to the first redistribution layer. The antenna pattern is disposed on the second insulating encapsulation opposite to the first redistribution layer. At least one of the first die and the third die is electrically coupled to the antenna pattern through the conductive through via and the first redistribution layer.

In an embodiment, the semiconductor package further comprises a conductive terminal. The conductive terminal is disposed on and electrically connected to the conductive connector. At least one of the first die and the third die is electrically coupled to the conductive terminal through the first redistribution layer and the conductive connector.

A manufacturing method of a semiconductor package comprises the following steps: forming a first redistribution layer on a temporary carrier; forming a plurality of conductive connectors on the first redistribution layer and electrically connected to the first redistribution layer; disposing a first die on the first redistribution layer, wherein after forming the conductive connectors and disposing the first die, the first die is surrounded by the conductive connectors, and the first die is electrically connected to the conductive connectors through the first redistribution layer; forming a first insulating encapsulation on the first redistribution layer to encapsulate the first die; and forming a plurality of conductive terminals on the conductive connectors.

In an embodiment, before forming the conductive terminals, each of the conductive connectors has a protruded portion protruded from the first insulating encapsulation; and the conductive terminals are formed to cover the protruded portions of the conductive connectors.

In an embodiment, the manufacturing method further comprises the following steps: forming a second redistribution layer on the first insulating encapsulation and electrically connected to the conductive connectors, wherein the plurality of conductive terminals are formed on the second redistribution layer and electrically connected to the second redistribution layer.

In an embodiment, the manufacturing method further comprises the following steps: preforming a planarization process to level the first insulating encapsulation and the conductive connectors before forming the second redistribution layer.

In an embodiment, the manufacturing method further comprises the following steps: disposing a second die on the first redistribution layer and electrically connected to the first redistribution layer, wherein the second die is disposed aside the first die and encapsulated by the first insulating encapsulation, and the first insulating encapsulation further encapsulate the second die.

In an embodiment, the manufacturing method further comprises the following steps: removing the temporary carrier from the first redistribution layer; and disposing a third die on the first redistribution layer opposite to the first die and electrically connected to the first redistribution layer.

In an embodiment, the manufacturing method further comprises the following steps: disposing a second die on the first redistribution layer and electrically connected to the first redistribution layer, wherein the first insulating encapsulation further encapsulate the second die; forming a second insulating encapsulation on the first redistribution layer to encapsulate the third die; forming a conductive through via penetrating through the second insulating encapsulation to connect to the first redistribution layer; and disposed an antenna pattern on the second insulating encapsulation opposite to the first redistribution layer, wherein at least one of the first die, the second die, or the third die is electrically coupled to the antenna pattern through the conductive through via and the first redistribution layer.

Based on the above, multiple dies or active/passive component(s) may be integrated into a single semiconductor package. The functional diversification and the size reduction of the semiconductor package may be enhanced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1E are schematic cross-sectional views illustrating a manufacturing method of a semiconductor package according to a first embodiment of the disclosure.

FIG. 2A to FIG. 2B are schematic cross-sectional views illustrating a manufacturing method of a semiconductor package according to a second embodiment of the disclosure.

FIG. 3A to FIG. 3D are schematic cross-sectional views illustrating a manufacturing method of a semiconductor package according to a third embodiment of the disclosure.

### DESCRIPTION OF THE EMBODIMENTS

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Moreover, the identical or similar numbers refer to the identical or similar elements throughout the drawings and have similar functions, materials or forming methods, so a detailed description is omitted.

Directional terms (e.g., up, down, right, left, front, back, top, bottom) as used herein are made only with reference to the figures as drawn and are not intended to imply absolute orientation.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

As used herein, the singular forms “a,” “an” and “the” include plural referents unless the context clearly dictates otherwise. For example, reference to a “component” includes aspects having two or more such components, unless the context clearly indicates otherwise. Unless otherwise indicated, “or” means “and/or”. As used herein, the term “and/or” includes any one and any combination of any two or more of the associated listed items.

It should be understood that when an element such as a layer, film, region or substrate is referred to as being “on another element,” “connected to another element,” or “overlapped to another element,” it can be directly on or connected to the other element, or intervening elements may also be present. In contrast, when an element is referred to as being “directly on” or “directly connected to” another element, there are no intervening elements present. As used herein, the term “connected” may refer to physically connected and/or electrically connected. Furthermore, the “electrical connection” or “coupling” of the two devices may indicate that there are other devices between the two devices.

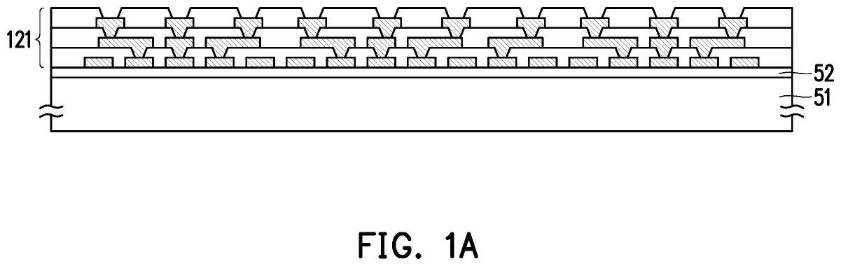

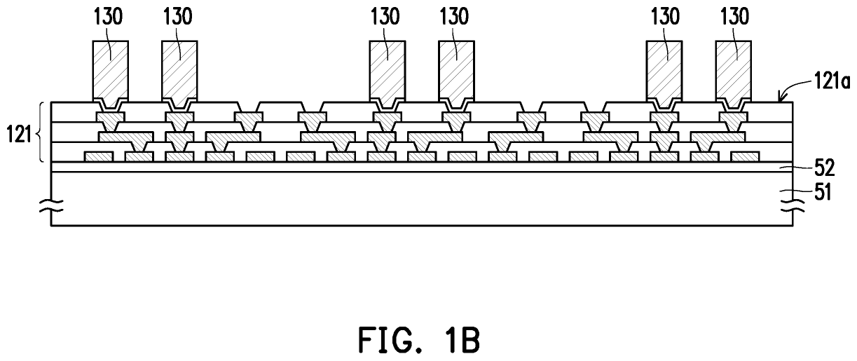

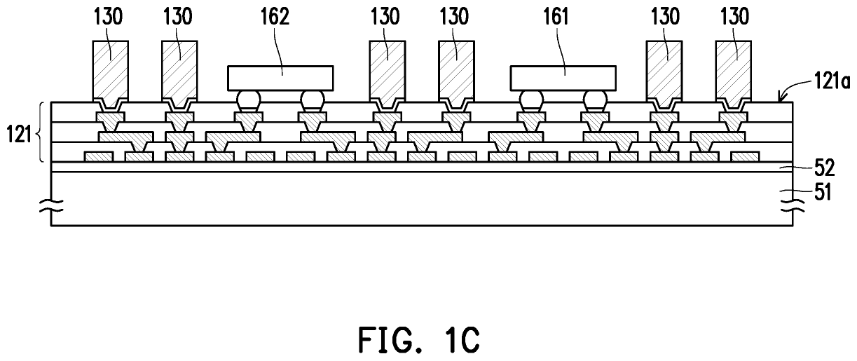

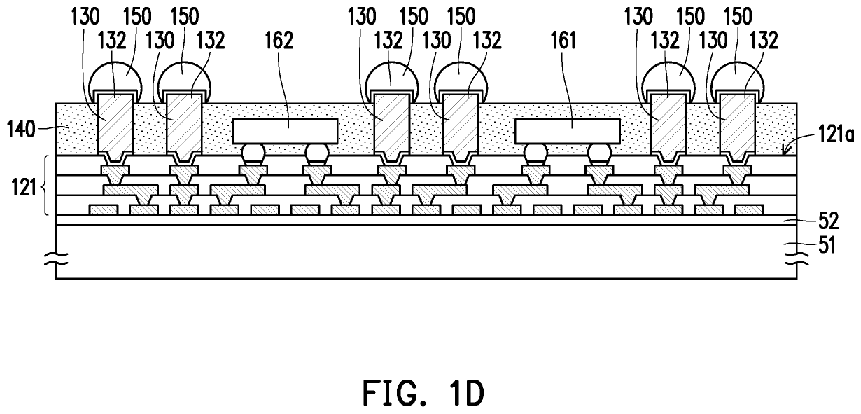

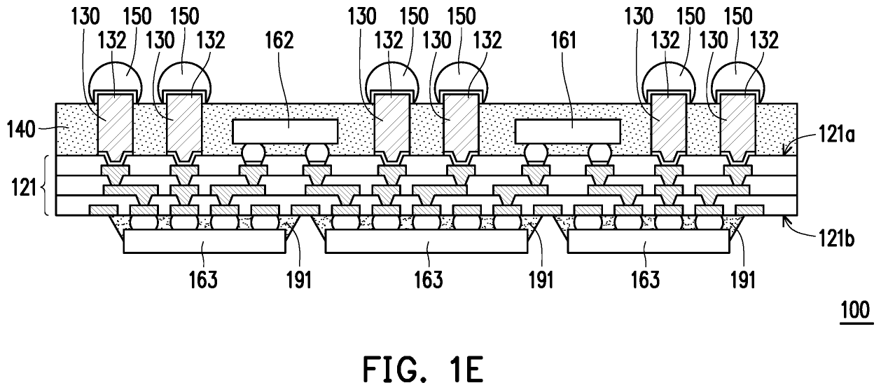

FIG. 1A to FIG. 1E are schematic cross-sectional views illustrating a manufacturing method of a semiconductor package according to a first embodiment of the disclosure.

Referring to FIG. 1A, a first redistribution layer 121 is formed over a temporary carrier 51. The temporary carrier 51 may be made of glass, plastic, silicon, metal, or other suitable materials as long as the material is able to withstand the subsequent processes while carrying a structure formed thereon. In an embodiment, a release layer 52 (e.g., a light to heat conversion film, or other suitable de-bonding layer) may be applied on the surface of the temporary carrier 51 to enhance the releasibility of the first redistribution layer 121 from the temporary carrier 51 in a subsequent process.

Referring to FIG. 1B, a plurality of conductive connectors 130 are formed on the first surface 121a of the first redistribution layer 121 to be electrically connected to the corresponding redistribution circuitry of the first redistribution layer 121.

In an embodiment, the conductive connectors 130 may be formed, for example, by photolithography, deposition, and/or electroplating process, but the disclosure is not limited thereto. In another embodiment, the conductive connectors 130 may include a preformed conductive post or a preformed conductive pillar.

Referring to FIG. 1C, a first die 161 is mounted on the first redistribution layer 121 to be electrically connected to the corresponding redistribution circuitry of the first redistribution layer 121. In an embodiment, the first die 161 may be a passive component such as capacitor, inductor, resistor, or any combination thereof.

In the embodiment, the first die 161 may be electrically connected to a corresponding conductive connector 130 through the corresponding redistribution circuitry of the first redistribution layer 121.

In the embodiment, a second die 162 may be mounted on the first surface 121a of the first redistribution layer 121 to be electrically connected to the corresponding redistribution circuitry of the first redistribution layer 121. In an embodiment, the second die 162 may be an active die. For example, the second die 162 may include an active circuit (e.g., RF, CMOS) built therein.

In an embodiment, the first die 161 and the second die 162 may be either active die or passive component.

In the embodiment, the second die 162 may be electrically connected to a corresponding conductive connector 130 or the first die 161 through the corresponding redistribution circuitry of the first redistribution layer 121.

In an embodiment, the first die 161 may be disposed on the first redistribution layer 121 surrounded by the conductive connectors 130, but the disclosure is not limited thereto.

In an embodiment, the second die 162 may be disposed aside to the first die 161, but the disclosure is not limited thereto.

It should be noted that the order of forming the conductive connectors 130, mounting the first die 161, and mounting the second die 162 are not limited in the embodiment. For example, the conductive connectors 130 may be formed first as shown in FIG. 1B, and then the first die 161 and/or the second die 162 may be disposed as shown in FIG. 1C. In an embodiment not shown, the conductive connectors 130 may be formed after the die (e.g., the first die 161 and/or the second die 162) is disposed.

Referring to FIG. 1D, a first insulating encapsulation 140 is formed on the first surface 121a of the first redistribution layer 121 to encapsulate the first die 161. In the embodiment, the first insulating encapsulation 140 may further encapsulate the second die 162.

In an embodiment, the material of the first insulating encapsulation 140 may include a molding material, but the disclosure is not limited thereto.

In the embodiment, the first insulating encapsulation 140 may expose a portion of each conductive connectors 130. For example, each of the conductive connectors 130 has a protruded portion 132 protruded from the first insulating encapsulation 140.

Referring to FIG. 1D, after forming the first insulating encapsulation 140, a plurality of conductive terminals 150 is formed on the conductive connectors 130. In an embodiment, the conductive terminal 150 may be a solder ball, but the disclosure is not limited thereto.

In the embodiment, the conductive terminal 150 may be formed to cover the protruded portion 132 of each conductive connector 130.

Referring to FIG. 1E, the temporary carrier 51 (as shown in FIG. 1D) may be removed from the second surface 121b of the first redistribution layer 121, wherein the second surface 121b is a surface opposite to the first surface 121a. For example, the temporary carrier 51 may be removed from the second surface 121b of the first redistribution layer 121 by applying external energy to the release layer 52 (as shown in FIG. 1D) located between the redistribution structure and the temporary carrier 51 so as to peel off the release layer 52. Other suitable processes may be used to remove the temporary carrier 51 and the release layer 52. A cleaning process is optionally performed on the bottom surface of the redistribution structure to remove the residue of the release layer 52.

Referring to FIG. 1E, after the second surface 121b of the first redistribution layer 121 being exposed, a third die 163 may be mounted on the second surface 121b of the first redistribution layer 121 to be electrically connected to the corresponding redistribution circuitry of the first redistribution layer 121.

In an embodiment, the third die 163 may be an active die. For example, the third die 163 may include an active circuit (e.g., RF, CMOS) built therein.

In an embodiment, the third die 163 may be referred to a semiconductor die having electrical functions that contribute to the electrical operation of the semiconductor package 100.

In an embodiment, the second die 162 embedded in the first insulating encapsulation 140 may include an active circuit built therein and may have the same or different function from the third die 163.

In an embodiment, an underfill 191 may be formed between the third die 163 and the first redistribution layer 121.

Up to here, the manufacturing process of a semiconductor package 100 is substantially complete.

In the embodiment, the semiconductor package 100 includes a first redistribution layer 121, a first die 161, a conductive connector 130, and a first insulating encapsulation 140. The first die 161 is disposed on the first redistribution layer 121 and is electrically connected to the first redistribution layer 121. The conductive connector 130 is disposed on the first redistribution layer 121 and is electrically connected to the first redistribution layer 121. The first insulating encapsulation 140 is disposed on the first redistribution layer 121 and encapsulates the first die 161 and the conductive connector 130.

In the embodiment, the conductive connector 130 may be disposed aside the first die 161, but the disclosure is not limited thereto.

In the embodiment, the semiconductor package 100 may further include a conductive terminal 150. The conductive terminal 150 may be disposed on and electrically connected to the conductive connector 130.

In the embodiment, each of the conductive connectors 130 may have a protruded portion 132 protruded from the first insulating encapsulation 140, and the conductive terminal 150 may cover the protruded portion 132 of the conductive connector 130.

In the embodiment, the semiconductor package 100 may further include a second die 162. The second die 162 may be disposed on and electrically connected to the first redistribution layer 121. The first insulating encapsulation 140 may further encapsulate the second die 162.

In an embodiment, the second die 162 may be mounted aside the first die 161, but the disclosure is not limited thereto.

In an embodiment, the first die 161 or the second die 162 may be either an active die or a passive component (e.g., a capacitor, an inductor, a resistor, or any combination thereof), but the disclosure is not limited thereto.

In the embodiment, the semiconductor package 100 may further include a third die 163. The third die 163 may be disposed on and electrically connected to the first redistribution layer 121. The third die 163 and the first die 161 may be disposed on two opposite sides of the first redistribution layer 121.

In an embodiment, the first die 161 may be electrically coupled to the second die 162 through the corresponding redistribution circuitry of the first redistribution layer 121.

In an embodiment, the first die 161, the second die 162, and/or the third die 163 may be electrically coupled to the conductive terminal 150 through the corresponding redistribution circuitry of the first redistribution layer 121 and the corresponding conductive connector 130.

In the embodiment, the semiconductor package 100 may be a substrate-less semiconductor package having multiple dies or active/passive component(s) (e.g., the first die 161, the second die 162, and/or the third die 163) integrated therein.

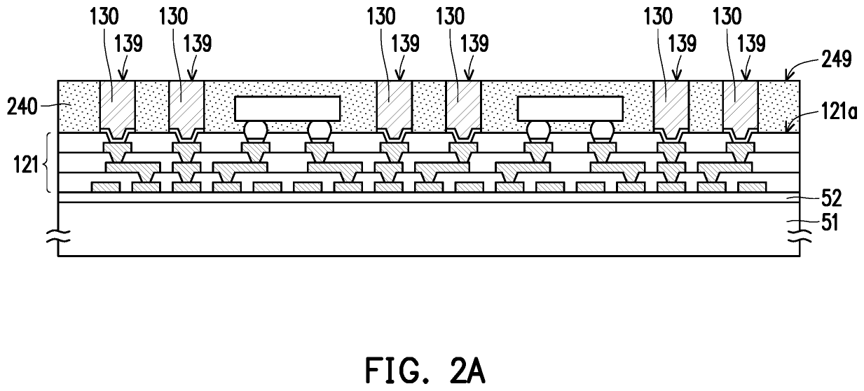

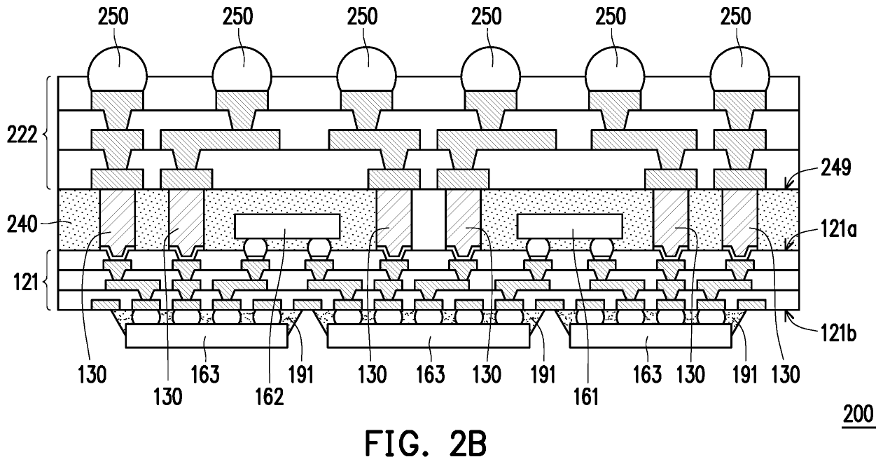

FIG. 2A to FIG. 2B are schematic cross-sectional views illustrating a manufacturing method of a semiconductor package 100 according to a second embodiment of the disclosure. In the exemplary embodiment of the disclosure, a manufacturing method of a semiconductor package 200 is similar to a manufacturing method of a semiconductor package 100. Specifically, FIGS. 2A to 2B are schematic cross-sectional views illustrating a manufacturing method of a semiconductor package 200 following the step shown in FIG. 1C.

Referring to FIG. 2A, a first insulating encapsulation 240 is formed on the first surface 121a of the first redistribution layer 121 to encapsulate the first die 161. In the embodiment, the first insulating encapsulation 240 may further encapsulate the second die 162.

In the embodiment, the first insulating encapsulation 240 may expose a top surface 139 of each conductive connector 130.

In the embodiment, the top surfaces 139 of conductive connectors 130 and the top surface 249 of the first insulating encapsulation 240 may be coplanar. For example, an insulating material (e.g., an insulating molding material) may be formed on the first surface 121a of the first redistribution layer 121. After forming the aforementioned insulating material, a planarization process (e.g., an etching process, a polishing process, a grinding process, or any combination thereof) may be preformed to reduce the thickness of the aforementioned insulating material, and/or the height of the conductive connectors 130. The insulation material after performing the aforementioned planarization process may be referred as the first insulating encapsulation 240, and/or the conductive connectors 130 after performing the aforementioned planarization process may be still referred as the conductive connectors 130.

Referring to FIG. 2B, a second redistribution layer 222 may be formed on the first insulating encapsulation 240 and electrically connected to the conductive connectors 130. The conductive connector 130 may be electrically connected to the corresponding redistribution circuitry of the second redistribution layer 222.

Referring to FIG. 2B, after forming the second redistribution layer 222, a plurality of conductive terminals 250 may be formed on the second redistribution layer 222. In an embodiment, the conductive terminal 250 may be a solder ball, but the disclosure is not limited thereto.

Up to here, the manufacturing process of a semiconductor package 200 is substantially complete.

In the embodiment, the semiconductor package 200 may include a first redistribution layer 121, a first die 161, a conductive connector 130, a first insulating encapsulation 240, and a second redistribution layer 222. The first insulating encapsulation 240 is disposed on the first redistribution layer 121 and encapsulates the first die 161 and the conductive connector 130. The second redistribution layer 222 is disposed on the first insulating encapsulation 240 and electrically connected to the conductive connectors 130. The top surfaces 139 of conductive connectors 130, the top surface 249 of the first insulating encapsulation 240, and the bottom surface of the second redistribution layer 222 are coplanar.

In the embodiment, the pitch or line/spacing (L/S) of the first redistribution layer 121 may be finer than the pitch or line/spacing (LS) of the second redistribution layer 222, but the disclosure is not limited thereto.

In the embodiment, the semiconductor package 200 may further include a plurality of conductive terminals 250. The conductive terminals 250 are disposed on the second redistribution layer 222 and electrically connected to the corresponding redistribution circuitry of the second redistribution layer 222.

In the embodiment, the semiconductor package 200 may be a substrate-less semiconductor package having multiple dies or active/passive component(s) (e.g., the first die 161, the second die 162, and/or the third die 163) integrated therein.

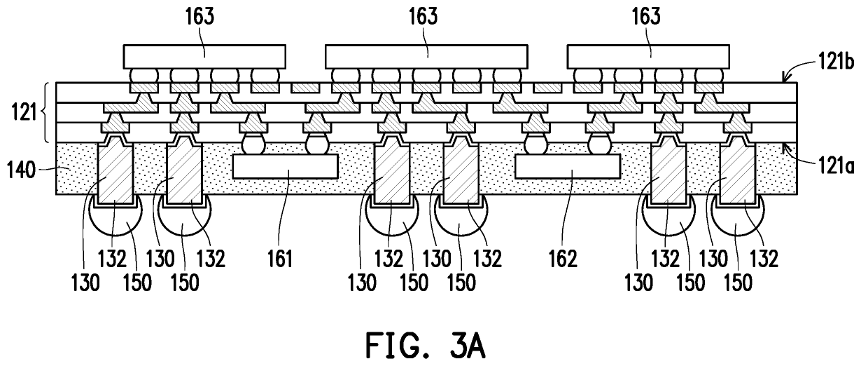

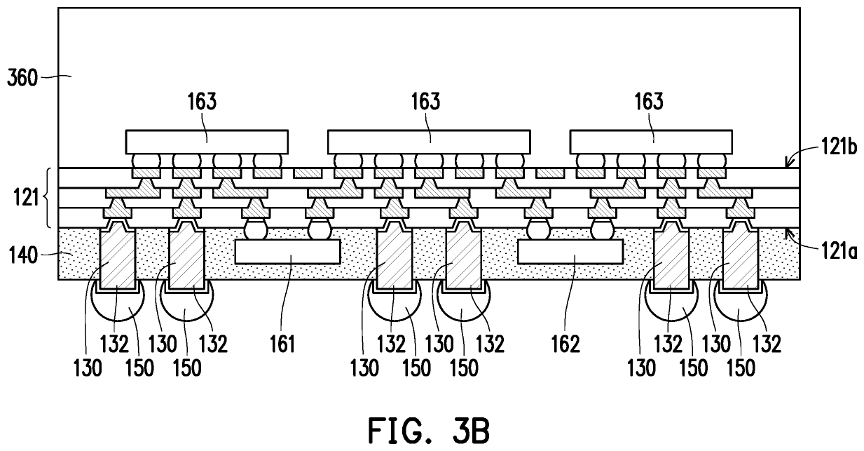

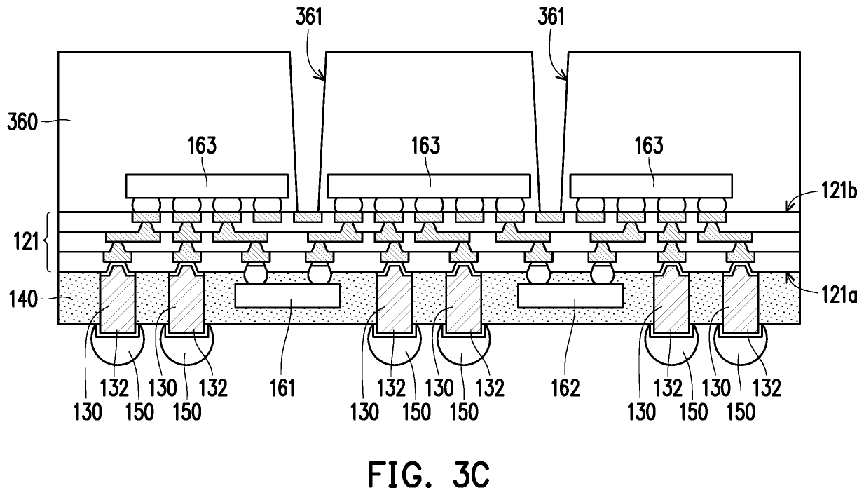

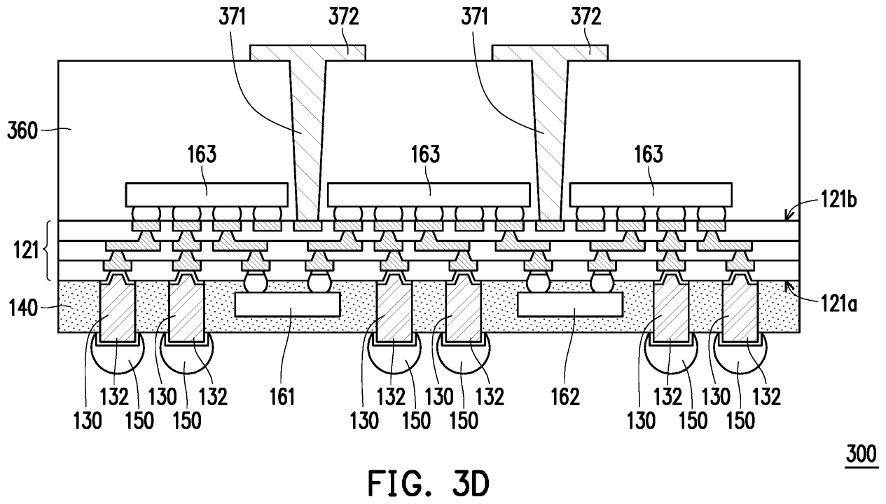

FIG. 3A to FIG. 3D are schematic cross-sectional views illustrating a manufacturing method of a semiconductor package 100 according to a third embodiment of the disclosure. In the exemplary embodiment of the disclosure, a manufacturing method of a semiconductor package 300 is similar to a manufacturing method of a semiconductor package 100. Specifically, FIGS. 3A to 3D are schematic cross-sectional views illustrating a manufacturing method of a semiconductor package 300 following the step shown in FIG. 1D.

Referring to FIG. 3A, the similar structure as shown in FIG. 1D may be flipped/rotated upside down. Moreover, after removing the temporary carrier 51 (as shown in FIG. 1D) and exposing the second surface 121b of the first redistribution layer 121, a third die 163 may be mounted on the second surface 121b of the first redistribution layer 121.

It should be noted that the order of flipping/rotating the structure upside down and removing the temporary carrier 51 (as shown in FIG. 1D) are not limited in the embodiment.

It should be noted that the conductive terminals 150 (e.g., solder balls) may be optionally formed on the conductive connectors 130, and/or an underfill (e.g., an underfill 191 as shown in FIG. 1E) may be optionally formed between the first redistribution layer 121 and third die 163.

Referring to FIG. 3B, after mounting the third die 163, a second insulating encapsulation 360 may be formed on the second surface 121b of the first redistribution layer 121 to encapsulate the third die 163.

In an embodiment, the material of the second insulating encapsulation 360 may include a molding material. For example, the material of the second insulating encapsulation 360 may be the same or similar to the material of the first insulating encapsulation 140.

In an embodiment, the second insulating encapsulation 360 may include a polymeric material having proper dielectric performance (e.g., dielectric constant (Dk) and dissipation factor (Df)) for next generation of mobile networks (e.g., 5G, or 5^{th} generation mobile networks). The material of the second insulating encapsulation 360 may further have proper mechanical performance (e.g., elastic modulus, coefficient of thermal expansion (CTE), etc.).

Referring to FIG. 3C, a portion of the second insulating encapsulation 360 may be removed to form a through hole 361. For example, at least a portion of the conductive pattern of the first redistribution layer 121 may be exposed by the through hole 361 for further electrical connection. The through hole 361 may be formed by preforming drilling (e.g., laser drilling), etching or other suitable process.

Referring to FIG. 3D, after forming the through hole 361 (as shown in FIG. 3C), a conductive material (e.g., copper, copper alloy, etc.) may be formed by plating, deposition, or other suitable process to form a conductive through via 371 and/or an antenna pattern 370. For example, a portion of the conductive material formed in the through hole 361 may be served as the conductive through via 371, and/or another portion of the conductive material formed on an outer surface of the second insulating encapsulation 360 may be served as the antenna pattern 370.

In an embodiment, the conductive through via 371 may be directly connected to the conductive pattern of the first redistribution layer 121.

In an embodiment, the conductive through via 371 may be referred to as a through mold via (TMV).

It should be noted that the conductive through via 371 having tapered profile as shown in FIG. 3D is merely exemplary. In an embodiment not shown, the conductive through via 371 may have vertical sidewalls relative to the second surface 121b of the first redistribution layer 121.

In the embodiment, the antenna pattern 370 is formed on the conductive through vias 371 to be electrically coupled to the corresponding redistribution circuitry of the first redistribution layer 121. In an embodiment, the antenna pattern 370 may be electrically coupled to at least one of the first die 161, the second first die 161, or the third die 163 through the corresponding conductive via and the corresponding redistribution circuitry of the first redistribution layer 121.

Up to here, the manufacturing process of a semiconductor package 300 having antenna is substantially complete.

In the embodiment, the semiconductor package 300 includes a first redistribution layer 121, a first die 161, a conductive connector 130, a first insulating encapsulation 140, a third die 163, a second insulating encapsulation 360, a conductive through via 371, and an antenna pattern 370. The second insulating encapsulation 360 is disposed on the first redistribution layer 121 and encapsulating the third die 163. The conductive through via 371 penetrates through the second insulating encapsulation 360 to be connected to the corresponding redistribution circuitry of the first redistribution layer 121. The antenna pattern 370 is disposed on the second insulating encapsulation 360 opposite to the first redistribution layer 121. At least one of the first die 161 and the third die 163 is electrically coupled to the antenna pattern 370 through the corresponding conductive through via 371 and the corresponding redistribution circuitry of the first redistribution layer 121.

In the embodiment, the semiconductor package 300 is a substrate-less semiconductor package having multiple dies or active/passive component(s) (e.g., the first die 161, the second die 162, and/or the third die 163) and antenna (e.g., antenna pattern 370) integrated therein.

Based on the above, multiple dies or active/passive component(s) may be integrated into a single semiconductor package. The functional diversification and the size reduction of the semiconductor package may be enhanced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A semiconductor package, comprising:
a first redistribution layer;
a first die, disposed on and electrically connected to the first redistribution layer;
a conductive connector, disposed on and electrically connected to the first redistribution layer, the conductive connector being disposed aside the first die; and
a first insulating encapsulation, disposed on the first redistribution layer and encapsulating the first die and the conductive connector.

2. The semiconductor package according to claim 1, further comprising:
a conductive terminal, disposed on and electrically connected to the conductive connector, wherein each of the conductive connectors has a protruded portion protruded from the first insulating encapsulation, and the conductive terminals cover the protruded portions of the conductive connectors.

3. The semiconductor package according to claim 1, further comprising:
a third die, disposed on and electrically connected to the first redistribution layer, wherein the third die and the first die are disposed on two opposite sides of the first redistribution layer, and the first die is electrically coupled to the third die through the first redistribution layer.

4. The semiconductor package according to claim 1, further comprising:
a second die, disposed on and electrically connected to the first redistribution layer, wherein the second die is disposed aside the first die and is encapsulated by the first insulating encapsulation.

5. The semiconductor package according to claim 1, further comprising:
a third die, disposed on and electrically connected to the first redistribution layer, wherein the third die and the first die are disposed on two opposite sides of the first redistribution layer, and the first die is electrically coupled to the third die through the first redistribution layer;
a second die, disposed on and electrically connected to the first redistribution layer, wherein the second die is disposed aside the first die and is encapsulated by the first insulating encapsulation; and
a conductive terminal, disposed on and electrically connected to the conductive connector, wherein at least one of the first die, the second die, or the third die is electrically coupled to the conductive terminal through the first redistribution layer and the conductive connector.

6. The semiconductor package according to claim 1, further comprising:
a conductive terminal, disposed on and electrically connected to the conductive connector; and
a second redistribution layer, disposed on the first insulating encapsulation and electrically connected to the conductive connectors, wherein the plurality of conductive terminals are formed on the second redistribution layer and electrically connected to the second redistribution layer.

7. The semiconductor package according to claim 6, wherein the top surfaces of conductive connectors and the top surface of the first insulating encapsulation are coplanar.

8. The semiconductor package according to claim 1, further comprising:
a third die, disposed on and electrically connected to the first redistribution layer, wherein the third die and the first die are disposed on two opposite sides of the first redistribution layer, and the first die is electrically coupled to the third die through the first redistribution layer;
a second insulating encapsulation, disposed on the first redistribution layer and encapsulating the third die;
a conductive through via, penetrating through the second insulating encapsulation to be connected to the first redistribution layer; and
an antenna pattern, disposed on the second insulating encapsulation opposite to the first redistribution layer, wherein at least one of the first die and the third die is electrically coupled to the antenna pattern through the conductive through via and the first redistribution layer.

9. The semiconductor package according to claim 8, further comprising:
a conductive terminal, disposed on and electrically connected to the conductive connector, wherein at least one of the first die and the third die is electrically coupled to the conductive terminal through the first redistribution layer and the conductive connector.

10. A manufacturing method of a semiconductor package, comprising:
forming a first redistribution layer on a temporary carrier;
forming a plurality of conductive connectors on the first redistribution layer and electrically connected to the first redistribution layer;
disposing a first die on the first redistribution layer, wherein after forming the conductive connectors and disposing the first die, the first die is surrounded by the conductive connectors, and the first die is electrically connected to the conductive connectors through the first redistribution layer;
forming a first insulating encapsulation on the first redistribution layer to encapsulate the first die; and
forming a plurality of conductive terminals on the conductive connectors.

11. The method according to claim 10, wherein:
before forming the conductive terminals, each of the conductive connectors has a protruded portion protruded from the first insulating encapsulation; and
the conductive terminals are formed to cover the protruded portions of the conductive connectors.

12. The method according to claim 10, further comprising:
forming a second redistribution layer on the first insulating encapsulation and electrically connected to the conductive connectors, wherein the plurality of conductive terminals are formed on the second redistribution layer and electrically connected to the second redistribution layer.

13. The method according to claim 12, further comprising:
preforming a planarization process to level the first insulating encapsulation and the conductive connectors before forming the second redistribution layer.

14. The method according to claim 10, further comprising:
disposing a second die on the first redistribution layer and electrically connected to the first redistribution layer, wherein the second die is disposed aside the first die and is encapsulated by the first insulating encapsulation, and the first insulating encapsulation further encapsulate the second die.

15. The method according to claim 10, further comprising:
removing the temporary carrier from the first redistribution layer; and
disposing a third die on the first redistribution layer opposite to the first die and electrically connected to the first redistribution layer.

16. The method according to claim 15, further comprising:
disposing a second die on the first redistribution layer and electrically connected to the first redistribution layer, wherein the first insulating encapsulation further encapsulate the second die;
forming a second insulating encapsulation on the first redistribution layer to encapsulate the third die;
forming a conductive through via penetrating through the second insulating encapsulation to connect to the first redistribution layer; and
disposed an antenna pattern on the second insulating encapsulation opposite to the first redistribution layer, wherein at least one of the first die, the second die, or the third die is electrically coupled to the antenna pattern through the conductive through via and the first redistribution layer.
